(19) United States
(12) Patent Application Publication
(10) Pub. No.: US 2024/0422972 A1
(43) Pub. Date: Dec. 19, 2024

(54) SEMICONDUCTOR MEMORY DEVICE

(71) Applicant: SK hynix Inc., Icheon-si Gyeonggi-do (KR)

(72) Inventors: Won Geun CHOI, Icheon-si Gyeonggi-do (KR); In Su PARK, Icheon-si Gyeonggi-do (KR); Jung Shik JANG, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 18/514,991

(22) Filed: Nov. 20, 2023

(30) Foreign Application Priority Data
Jun. 13, 2023 (KR) 10-2023-0075512

(51) Int. Cl. H10B 43/23; H10B 43/10

(52) U.S. Cl. CPC H10B 43/23; H10B 43/10

(57) ABSTRACT

The present disclosure relates to a semiconductor memory device. The semiconductor memory device includes a gate stack, a hole penetrating the gate stack, and a channel structure. The hole has an undercut region defined on a sidewall thereof. The channel structure covers a portion of the undercut region and opens another portion of the undercut region.

### CROSS-REFERENCE TO RELATED APPLICATION

The present application claims priority under 35 U.S.C. § 119 (a) to Korean patent application number 10-2023-0075512 filed on Jun. 13, 2023, in the Korean Intellectual Property Office, the entire disclosure of which is incorporated by reference herein.

### BACKGROUND

### 1. Technical Field

Various embodiments of the present disclosure generally relate to an electronic device, and more particularly, to a semiconductor memory device.

### 2. Related Art

It is well known that semiconductor memory devices have become ubiquitous. The demand for semiconductor memory devices therefore continues to increase.

A semiconductor memory device may include a memory cell for storing data. To obtain a semiconductor memory device with a large capacity, the technique for three-dimensional semiconductor memory devices including three-dimensionally arranged memory cells has been developed.

### SUMMARY

According to an embodiment, a semiconductor memory device may include a gate stack comprising a first sub-stack, a second sub-stack, and a third sub-stack, the first to third sub-stacks being stacked on top of each other in a first direction, and a cell plug extending in the first direction penetrating the first sub-stack, the second sub-stack, and the third sub-stack, wherein the cell plug comprises a first region penetrating the first sub-stack, a second region penetrating the second sub-stack, and a third region penetrating the third sub-stack, each of the first, second and third regions having top and bottom ends, each of the top and bottom ends having a corresponding area, wherein the area of the top end of the first region of the cell plug is greater than the area of bottom end of the second region of the cell plug, and wherein the upper end of the second region of the cell plug has an area greater than the area of the bottom end of the third region.

According to an embodiment, a semiconductor memory device may include a gate stack comprising a plurality of conductive layers spaced apart and stacked on each other in a first direction, a hole extending in the first direction and penetrating the plurality of conductive layers, a channel structure comprising a first channel pillar and a second channel pillar extending in the first direction, the channel structures being located in the hole and spaced apart from each other in a second direction, the second direction lying in a plane substantially parallel with the plurality of conductive layers, and a memory layer located between the gate stack and each of the first channel pillar and the second channel pillar, wherein a curved portion defining an undercut region is formed on a sidewall of the hole, wherein the undercut region comprises a first portion in the second direction and a second portion in a third direction crossing the second direction in the plane, and wherein the channel structure covers the first portion of the undercut region and opens the second portion of the undercut region.

### BRIEF DESCRIPTION OF THE DRAWINGS

FIGS. 1A and 1B are perspective views of a semiconductor memory device according to embodiments of the present disclosure;

FIG. 2 is a circuit diagram illustrating a memory cell array according to an embodiment of the present disclosure;

FIGS. 3A, 3B, 3C, and 3D are vertical cross-sectional diagrams illustrating a first structure and a second structure of a semiconductor memory device according to an embodiment of the present disclosure;

FIG. 4 is a perspective view of a semiconductor memory device according to an embodiment of the present disclosure;

FIGS. 5A and 5B are vertical cross-sectional diagrams illustrating a semiconductor memory device according to an embodiment of the present disclosure;

FIGS. 6A and 6B are diagrams illustrating a portion of a semiconductor memory device according to an embodiment of the present disclosure;

FIGS. 7A, 7B, and 7C are vertical cross-sectional diagrams illustrating portions of a semiconductor memory device according to embodiments of the present disclosure;

FIGS. 8A and 8B are perspective views diagrams illustrating steps of a method of manufacturing a semiconductor memory device according to embodiments of the present disclosure;

FIG. 9 is a vertical cross-sectional diagram illustrating a part of an internal structure taken along line a minor axis of a hole shown in FIG. 8B;

FIG. 10 is a vertical cross-sectional diagram illustrating a semiconductor memory device according to a comparative example; and

FIG. 11 is a block diagram illustrating an electronic system including a semiconductor memory device according to embodiments of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be modified in various forms and replaced with other equivalent embodiments. Thus the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms.

Embodiments provide a semiconductor memory device capable of improving operational reliability.

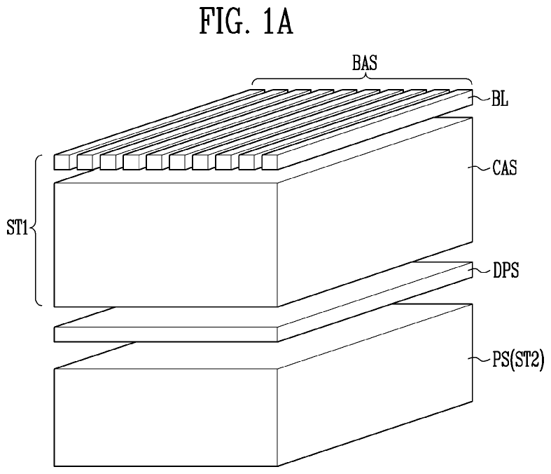

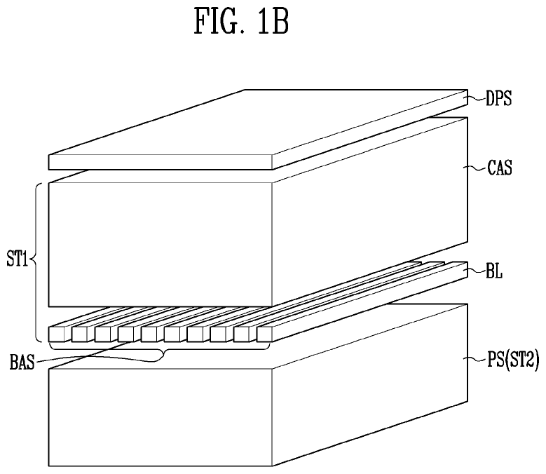

FIGS. 1A and 1B are perspective-view diagrams illustrating a semiconductor memory device according to embodiments of the present disclosure.

Referring to FIGS. 1A and 1B, the semiconductor memory device may include a first structure ST1, a second structure ST2, and a doped semiconductor structure DPS between the first structure ST1 and the second structure ST2. The first structure ST1 may include a cell array structure CAS and a bit line array structure BAS. The second structure ST2 may include a peripheral circuit structure PS.

The bit line array structure BAS may include a plurality of bit lines BL.

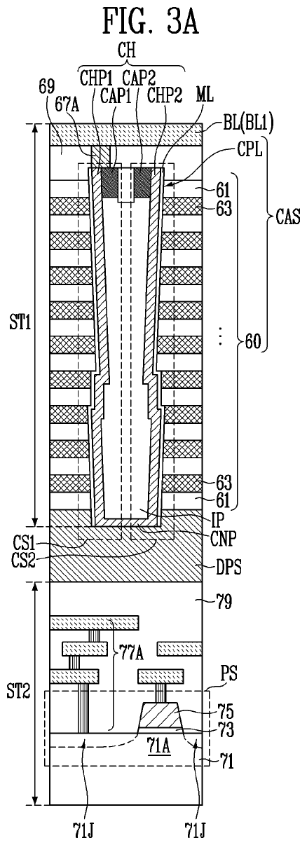

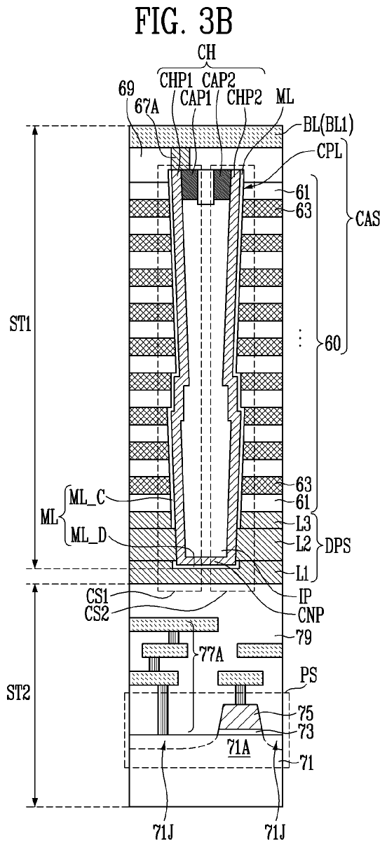

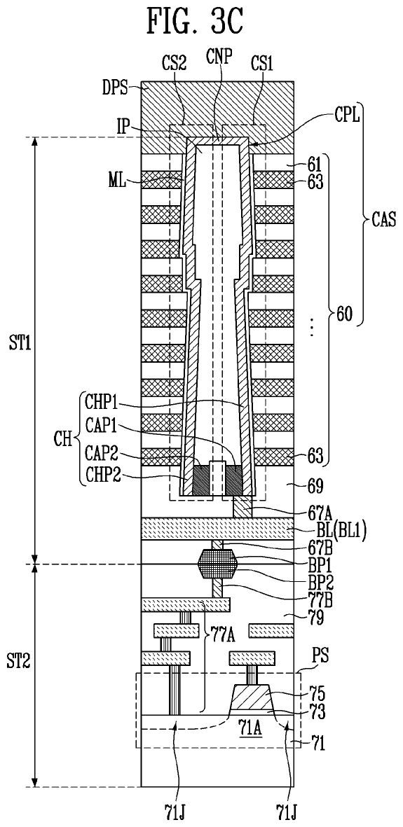

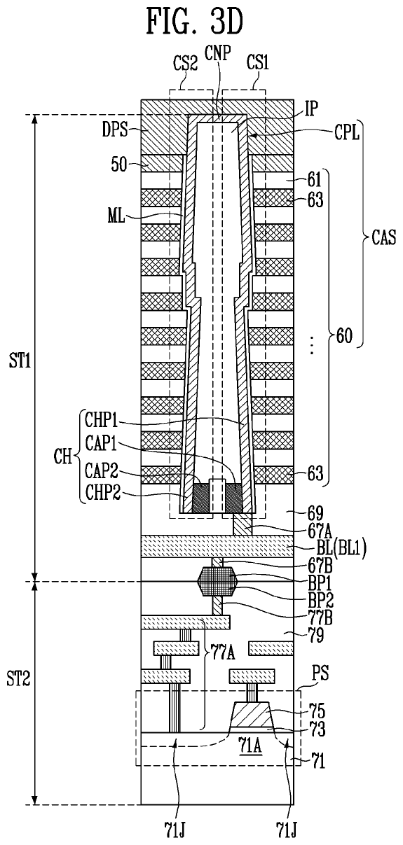

The cell array structure CAS may be located between the bit line array structure BAS and the doped semiconductor structure DPS and may include a memory block, not shown in FIG. 1A. The memory block may include a plurality of memory cell strings, which are electrically connected to the bit line array structure BAS and the doped semiconductor structure DPS. Each memory cell string may include a channel structure CH, which extends towards a bit line BL corresponding thereto from the doped semiconductor structure DPS. (See FIG. 3A, 3B, 3C or 3D.)

The doped semiconductor structure DPS may include at least one of an n-type impurity and a p-type impurity and may serve as at least one of a common source region and a well region. The doped semiconductor structure DPS may include a first conductivity-type doped region including n-type impurities as majority carriers. The doped semiconductor structure DPS may also include a second conductivity-type doped region including p-type impurities as majority carriers. The first conductivity-type doped region may be provided as a common source region, and the second conductivity-type doped region may be provided as a well region.

The peripheral circuit structure PS may be configured to perform three operations: 1) a program operation for storing data in a memory cell; 2) a read operation for outputting the data stored in the memory cell; and 3) an erase operation for erasing the data stored in the memory cell. The peripheral circuit structure PS may include an input/output circuit, a control circuit, a voltage generating circuit, a row decoder, a column decoder, and a page buffer. More specifically, the peripheral circuit structure PS may include a plurality of transistors, a capacitor, a resistor, and the like.

The peripheral circuit structure PS may include a region which overlaps/lies beneath the doped semiconductor structure DPS, the cell array structure CAS, and the bit line array structure BAS. The peripheral circuit structure PS may be vertically adjacent to the doped semiconductor structure DPS as shown in FIG. 1A, or to the bit line array structure BAS as shown in FIG. 1B.

The cell array structure CAS may be connected to the peripheral circuit structure PS through a plurality of select lines, a plurality of word lines, the bit line array structure BAS, and the doped semiconductor structure DPS. Though not shown in FIGS. 1A and 1B, each of the first structure ST1 and the second structure ST2 may include at least one of a plurality of interconnections, a plurality of contacts, and a plurality of conductive bonding pads for an electrical connection.

The cell array structure CAS may include a three-dimensional cell array structure which includes memory cells arranged in three dimensions.

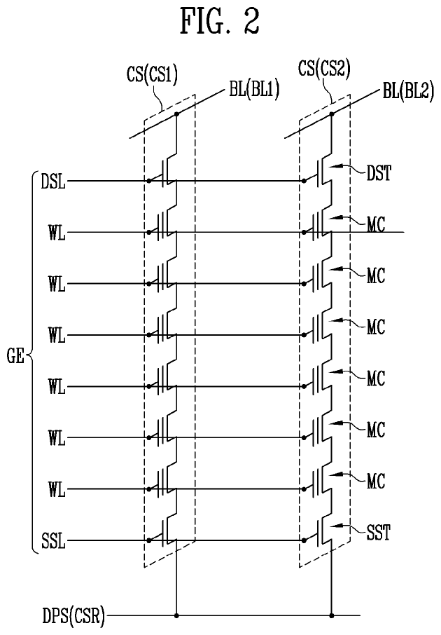

FIG. 2 is a circuit diagram illustrating a memory cell array according to an embodiment of the present disclosure.

Referring to FIG. 2, the memory cell array may include a plurality of memory cell strings CS. Each of the memory cell strings CS may include at least one source select transistor SST, a plurality of memory cell transistors MC, which are referred to hereafter as memory cells MC, and at least one drain select transistor DST. The plurality of memory cells MC may be coupled in series between the source select transistor SST and the drain select transistor DST. The source select transistor SST, the plurality of memory cells MC, and the drain select transistor DST of each cell string CS may be connected in series to each other by the channel structure CH. (See FIG. 3A, 3B, 3C or 3D.)

The channel structure CH may serve as a channel region of a memory cell string CS and include a semiconductor layer. The channel structure CH may be coupled to a common source region CSR and the bit line BL. The common source region CSR may be formed in the doped semiconductor structure DPS. A voltage may be applied to the common source region CSR so as to discharge a channel region potential of the memory cell string CS. A voltage may be applied to the bit line BL so as to precharge the channel region of the memory cell string CS.

Together, the gate electrodes GE of the source select transistor SST, the plurality of memory cells MC, and the drain select transistor DST may form a gate stack. The gate stack may include a source select line SSL provided as a gate electrode of the source select transistor SST, a plurality of word lines WL provided as a plurality of gate electrodes of the plurality of memory cells MC, and a drain select line DSL provided as a gate electrode of the drain select transistor DST.

A plurality of memory cell strings CS may be divided into a plurality of cell string groups. Two cell strings CS are shown in FIG. 2 and denominated CS1 and CS2. Each of the cell string groups may include at least two memory cell strings which are divided from the same cell plug CPL. (See FIG. 3A, 3B, 3C or 3D.) According to an embodiment, each of the cell string groups may include a first memory cell string CS1 and a second memory cell string CS2.

Both the first memory cell string CS1 and the second memory cell string CS2 may be coupled to common source region CSR. The first memory cell string CS1 and the second memory cell string CS2 may be individually controlled by the gate electrodes GE which are electrically and physically separated from each other, or by the bit lines BL which are also electrically and physically separated from each other. According to an embodiment, the first memory cell string CS1 and the second memory cell string CS2 may be coupled to the same gate electrode GE, and may be respectively coupled to a first bit line BL1 and a second bit line BL2.

FIGS. 3A, 3B, 3C, and 3D are vertical cross-sectional diagrams illustrating the first structure ST1 and the second structure ST2 of the semiconductor memory device according to embodiments of the present disclosure.

Referring to FIGS. 3A to 3D, the first structure ST1 may include the cell array structure CAS and the bit line BL which are described above with reference to FIGS. 1A and 1B. The cell array structure CAS may include a gate stack 60 and a cell plug CPL. The gate stack 60 may be arranged between the doped semiconductor structure DPS and the bit line BL. The cell plug CPL may penetrate the gate stack 60.

The gate stack 60 may include a plurality of interlayer insulating layers 61 and a plurality of conductive layers 63 which are stacked alternately with each other in a direction orthogonal to the bit line BL and by which the doped semiconductor structure DPS “faces” the bit line BL. The plurality of conductive layers 63 may form the source select line SSL, the drain select line DSL, and the plurality of word lines WL which are shown in FIG. 2.

The cell plug CPL may include a channel structure CH and a memory layer ML within the gate stack 60. Some regions of the memory layer ML may serve as data storage areas of the plurality of memory cells MC shown in FIG. 2. Other regions may serve as the drain select transistor DST and the source select transistor SST as shown in FIG. 2.

As described above with reference to FIG. 2, the cell plug CPL may be divided into two or more separate memory cell strings CS. According to an embodiment, the channel structure CH of the cell plug CPL may include a first channel pillar CHP1 and a second channel pillar CHP2 which are spaced apart from each other. The first channel pillar CHP1 may serve as a channel region of the first memory cell string CS1. The second channel pillar CHP2 may serve as a channel region of the second memory cell string CS2.

The channel structure CH may further include a capping pattern CAP1 or CAP2 which serves as a junction. The capping pattern CAP1 or CAP2 may form an end portion of the channel structure CH toward the bit line BL. According to an embodiment, the channel structure CH may include the first capping pattern CAP1 and the second capping pattern CAP2 which are spaced apart from each other. The first capping pattern CAP1 may contact the first channel pillar CHP1 and the second capping pattern CAP2 may contact the second channel pillar CHP2. Each of the first capping pattern CAP1 and the second capping pattern CAP2 may include a doped semiconductor layer which includes at least one of a p-type impurity and an n-type impurity. According to an embodiment, each of the first capping pattern CAP1 and the second capping pattern CAP2 may include an n-type doped semiconductor layer which includes n-type impurities as majority carriers.

The first structure ST1 may further include a first insulation structure 69 which covers the gate stack 60. The first insulation structure 69 may include a plurality of insulating layers. The bit line BL may be buried in the first insulation structure 69. The bit line BL may be coupled to the channel structure CH of the cell plug CPL. According to an embodiment, the bit line BL may be coupled to the channel structure CH through a bit line contact 67A in the first insulation structure 69.

FIGS. 3A to 3D are vertical cross-sectional diagrams taken along the first bit line BL1 coupled to the first channel pillar CHP1 of the first memory cell string CS1. Though not shown in FIGS. 3A to 3D, similarly to the first bit line BL1, the semiconductor memory device may further include the second bit line BL2 which is coupled to the second channel pillar CHP2 of the second memory cell string CS2.

Each of the first channel pillar CHP1 and the second channel pillar CHP2 may include a source-side end portion which faces in an opposite direction to the bit line BL. The source-side end portion of the first channel pillar CHP1 and the source-side end portion of the second channel pillar CHP2 may be coupled to each other through a connection pattern CNP near the doped semiconductor structure DPS. An insulating pillar IP may overlie the connection pattern CNP. The first channel pillar CHP1 and the second channel pillar CHP2 may be spaced apart from each other with the insulating pillar IP located therebetween. Together, the first channel pillar CHP1, the second channel pillar CHP2, and the connection pattern CNP may comprise the channel layer. Each of the first channel pillar CHP1 and the second channel pillar CHP2 may include a portion which is coupled to the doped semiconductor structure DPS.

Referring to FIG. 3A, each of the first channel pillar CHP1 and the second channel pillar CHP2 may penetrate the memory layer ML and include an end portion which contacts the doped semiconductor structure DPS. The doped semiconductor structure DPS may include at least one of an n-type impurity and a p-type impurity. According to an embodiment, the end portion of each of the first channel pillar CHP1 and the second channel pillar CHP2 may contact the common source region of the doped semiconductor structure DPS which includes n-type impurities as the majority carriers.

Referring to FIG. 3B, the doped semiconductor structure DPS may be coupled to a “side” portion of each of the first channel pillar CHP1 and the second channel pillar CHP2. The doped semiconductor structure DPS may include a first semiconductor layer L1 and a second semiconductor layer L2. The second semiconductor layer L2 may be located between the first semiconductor layer L1 and the gate stack 60. The doped semiconductor structure DPS may further include a third semiconductor layer L3 which is located between the second semiconductor layer L2 and the gate stack 60. The third semiconductor layer L3 may not be formed in some embodiments.

Each of the first to third semiconductor layers L1 to L3 may include at least one of an n-type impurity and a p-type impurity. According to an embodiment, each of the first to third semiconductor layers L1 to L3 may include n-type impurities as majority carriers. According to another embodiment, the first semiconductor layer L1 may include p-type impurities as majority carriers, and each of the second and third semiconductor layers L2 and L3 may include n-type impurities as majority carriers.

The second semiconductor layer L2 may penetrate a side portion of the memory layer ML so as to contact the side portion of each of the first channel pillar CHP1 and the second channel pillar CHP2. Therefore, the memory layer ML may be separated into a cell-side pattern ML_C and a dummy pattern ML_D. The cell-side pattern ML_C may be located between each of the first channel pillar CHP1 and the second channel pillar CHP2 and the gate stack 60. The dummy pattern ML_D may be located between the cell plug CPL and the first semiconductor layer L1.

Referring to FIG. 3C, each of the first channel pillar CHP1 and the second channel pillar CHP2 may include a portion extending upwardly such that the portion protrudes toward and into the doped semiconductor structure DPS more than the memory layer ML. The protrusion portion of each of the first channel pillar CHP1 and the second channel pillar CHP2 may contact the doped semiconductor structure DPS. The doped semiconductor structure DPS may include at least one of an n-type impurity and a p-type impurity.

Referring to FIG. 3D, a semiconductor layer 50 may be located between the doped semiconductor structure DSP and the gate stack 60. The semiconductor layer 50 may include a semiconductor material such as silicon or germanium. The semiconductor layer may 50 include a single-crystal semiconductor material or a polycrystalline semiconductor material. The semiconductor layer 50 may include an undoped semiconductor material, or a doped semiconductor material including at least one of an n-type impurity and a p-type impurity.

The memory layer ML, the first channel pillar CHP1, and the second channel pillar CHP2 may extend into and through the semiconductor layer 50. The first channel pillar CHP1 and the second channel pillar CHP2, but not the memory layer ML, may extend into the doped semiconductor structure DPS and contact the doped semiconductor structure DPS. The doped semiconductor structure DPS may include at least one of an n-type impurity and a p-type impurity.

Referring to FIGS. 3A to 3D, the second structure ST2 may include a semiconductor substrate 71, the peripheral circuit structure PS, a second insulation structure 79, and a plurality of interconnections 77A.

The semiconductor substrate 71 may include an active region 71A which is divided by an isolation layer (not shown). The peripheral circuit structure PS may include one or more transistors. A gate insulating layer 73 and a gate electrode 75 of a transistor may be stacked over the active region 71A of the semiconductor substrate 71. Source/drain junctions 71J of the transistor may be formed in the active region 71A at both ends of the gate electrode 75. The plurality of interconnections 77A may include sub-interconnections which are individually coupled to the gate electrode 75 and the source/drain junctions 71J.

The semiconductor substrate 71 and the peripheral circuit structure PS may be covered by the second insulation structure 79. The plurality of interconnections 77A may be arranged in the second insulation structure 79.

Referring to FIGS. 3A and 3B, the process of forming the doped semiconductor structure DPS and the process of forming the first structure ST1 may be performed on the second structure ST2.

Referring to FIGS. 3C and 3D, the process of forming the first structure ST1 and the process of forming the second structure ST2 may be separately performed. The first structure ST1 may further include a first contact 67B and a first conductive bonding pad BP1 which are located in the first insulation structure 69. The second structure ST2 may further include a second contact 77B and a second conductive bonding pad BP2 which are located in the second insulation structure 79. The first conductive bonding pad BP1 of the first structure ST1 and the second conductive bonding pad BP2 of the second structure ST2 may be coupled to each other by a bonding process. The doped semiconductor structure DPS may be provided after the bonding process.

The first conductive bonding pad BP1 may be electrically coupled to any one of the bit line BL and the conductive layers 63 through the first contact 67B. The second conductive bonding pad BP2 may be electrically coupled to any one of the elements which form the peripheral circuit structure PS through the second contact 77B. According to an embodiment, as shown in FIGS. 3C and 3D, the first contact 67B, the first conductive bonding pad BP1, the second conductive bonding pad BP2, and the second contact 77B may be used to electrically couple the bit line BL and the transistor which constitutes the page buffer of the peripheral circuit structure PS as shown in FIG. 1A or 1B.

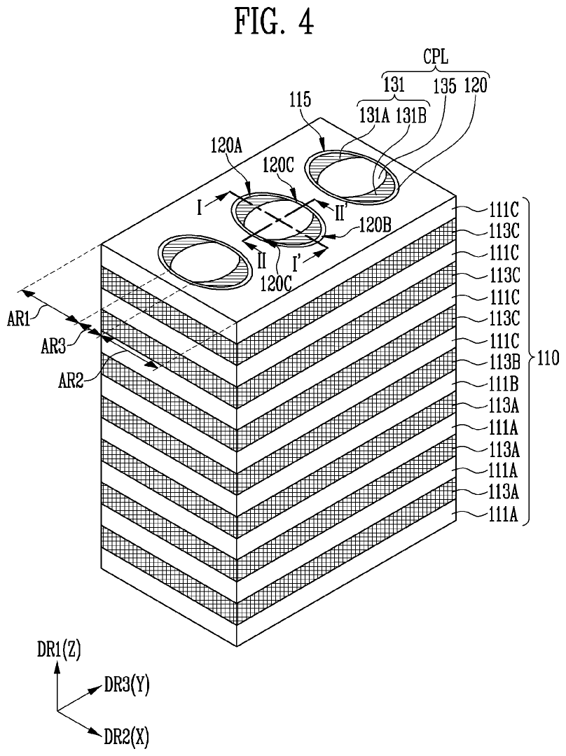

FIGS. 4, 5A, 5B, 6A, and 6B together illustrate an embodiment of a semiconductor memory device.

FIG. 4 is a perspective view of a semiconductor memory device according to an embodiment of the present disclosure.

Referring to FIG. 4, a hole 115 may penetrate a gate stack 110. The cell plug CPL may be formed in the hole 115.

The gate stack 110 may include a plurality of conductive layers 113A, 113B, and 113C which are spaced apart from each other in a first direction DR1 and stacked on each other. The gate stack 110 may further include a plurality of interlayer insulating layers 111A, 111B, and 111C which are alternately located with the plurality of conductive layers 113A, 113B, and 113C in the first direction DR1. Each of the plurality of conductive layers 113A, 113B, and 113C and the plurality of interlayer insulating layers 111A, 111B, and 111C may extend in the form of a plate. According to an embodiment shown in FIG. 4, each of the conductive layers 113A, 113B, and 113C and each of the interlayer insulating layers 111A, 111B, and 111C may lie in different X-Y planes. The first direction DR1 may be parallel to a Z-axis, which is mutually orthogonal to the X-axis and the Y-axis, which together define an X-Y plane.

Each layer of the conductive layers 113A, 113B, and 113C may serve as one of a plurality of word lines WL as shown in FIG. 2. Each layer of the plurality of conductive layers 113A, 113B, and 113C may include at least one of a doped semiconductor layer and a metal layer. The doped semiconductor layer may include a doped silicon layer. The metal layer may include tungsten, copper, molybdenum, or the like. Each layer of the plurality of conductive layers 113A, 113B, and 113C may further include a conductive metal nitride layer, such as a titanium nitride, a tantalum nitride, or the like. Each layer of the plurality of interlayer insulating layers 111A, 111B, and 111C may include a silicon oxide layer.

The hole 115 may extend in the first direction DR1 so as to penetrate the plurality of conductive layers 113A, 113B, and 113C and penetrate the plurality of interlayer insulating layers 111A, 111B, and 111C. The hole 115 may have a horizontal cross-sectional shape that is elliptical such that it has different widths in a second direction DR2 and a third direction DR3. The elliptical hole 115 may thus have its major axis in the second direction DR2 and its minor axis in the third direction DR3. The second direction DR2 may be the X-axis direction and the third direction DR3 may be the Y-axis direction.

The cell plug CPL may include a memory layer 120, a channel structure 131, and an insulating pillar 135. Each of the cell plug CPL and the insulating pillar 135 may have an elliptically-shaped horizontal cross section. The channel structure 131 may include a first channel pillar 131A and a second channel pillar 131B. The insulating pillar 135 may be located between the first channel pillar 131A and the second channel pillar 131B. The first channel pillar 131A and the second channel pillar 131B may be spaced apart from each other in the second direction DR2 on the X-Y plane by the elliptically-shape insulating pillar 135. Each of the first channel pillar 131A and the second channel pillar 131B may have a crescent-shaped horizontal cross section. The memory layer 120 may include a first memory portion 120A between the first channel pillar 131A and the gate stack 110 and a second memory portion 120B between the second channel pillar 131B and the gate stack 110. The memory layer 120 may further include a connection portion 120C.

The connection portion 120C may couple the first memory portion 120A and the second memory portion 120B to each other and be located between the insulating pillar 135 and the gate stack 110. Though not shown in FIG. 4, the connection portion 120C of the memory layer 120 may be removed. The insulating pillar 135 may extend between the first memory portion 120A and the second memory portion 120B of the memory layer 120 and may contact the gate stack 110.

The first channel pillar 131A and the second channel pillar 131B may each act as a channel region of a memory cell string corresponding thereto. The first channel pillar 131A and the second channel pillar 131B may each be made of a semiconductor material, such as silicon (Si), germanium (Ge), or a mixture thereof.

The insulating pillar 135 may include an insulating material such as a silicon oxide.

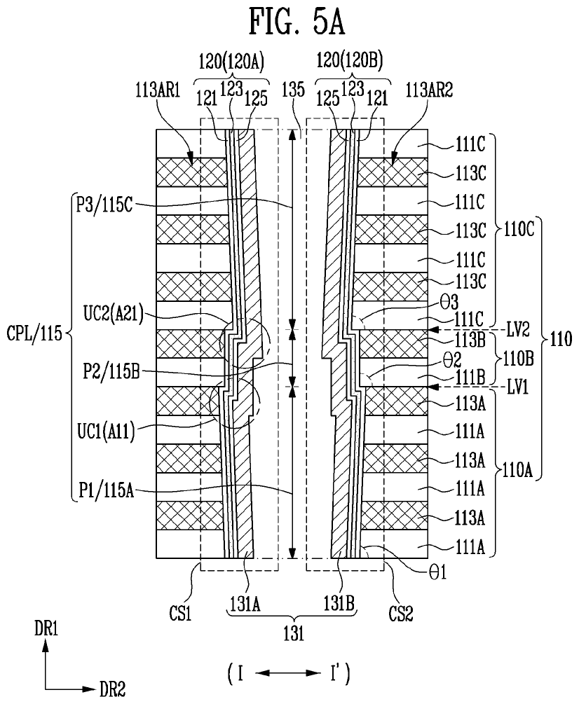

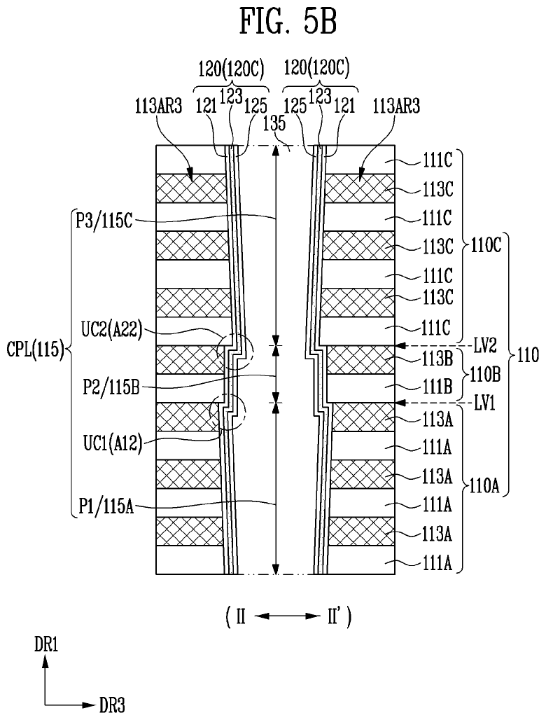

FIGS. 5A and 5B are vertical cross-sectional diagrams illustrating a semiconductor memory device according to an embodiment of the present disclosure. FIG. 5A is a vertical cross-sectional diagram of the semiconductor memory device taken along line I-I′ of FIG. 4. FIG. 5B is a cross-sectional diagram illustrating the semiconductor memory device taken along line II-II′ of FIG. 4.

Referring to FIGS. 5A and 5B, the plurality of interlayer insulating layers 111A, 111B, and 111C and the plurality of conductive layers 113A, 113B, and 113C of the gate stack 110 may be divided into sub-stacks, three of which are shown in the figure as being stacked on top of each other vertically in the first direction DR1. An elongated hole 115 may thus be made by aligning and coupling shorter openings or holes, which penetrate each of the sub-stacks.

According to an embodiment, the plurality of interlayer insulating layers 111A, 111B, and 111C and the plurality of conductive layers 113A, 113B, and 113C may be divided into a first sub-stack 110A, a second sub-stack 110B, and a third sub-stack 110C which are stacked on top of each other in the first direction DR1. The plurality of interlayer insulating layers 111A, 111B, and 111C may include a first interlayer insulating layer 111A of the first sub-stack 110A, a second interlayer insulating layer 111B of the second sub-stack 110B, and a third interlayer insulating layer 111C of the third sub-stack 110C. The plurality of conductive layers 113A, 113B, and 113C may include a first conductive layer 113A of the first sub-stack 110A, a second conductive layer 113B of the second sub-stack 110B, and a third conductive layer 113C of the third sub-stack 110C.

The cell plug CPL and the hole 115 may extend in the first direction DR1 so as to penetrate the first to third sub-stacks 110A to 110C. The cell plug CPL may include a first region P1 which penetrates the first sub-stack 110A, a second region P2 which penetrates the second sub-stack 110B, and a third region P3 which penetrates the third sub-stack 110C. The hole 115 may include a first opening portion 115A which penetrates the first sub-stack 110A, a second opening portion 115B which penetrates the second sub-stack 110B, and a third opening portion 115C which penetrates the third sub-stack 110C. The first region P1 of the cell plug CPL may be located in the first opening portion 115A of the hole 115. The second region P2 of the cell plug CPL may be located in the second opening portion 115B of the hole 115. The third region P3 of the cell plug CPL may be located in the third opening portion 115C of the hole 115.

From a plan view, seen in FIG. 4, each of the cell plug CPL and the hole 115 may extend horizontally in the second direction DR2 to a first width. The cell plug CPL and the hole 115 may also extend horizontally in the third direction DR3, which is mutually orthogonal to the first direction DR1 and the second direction DR2 to a second width. In an embodiment, the first width extension, which is in the second direction DR2, may be greater than the second width extension, which is in the third direction DR3.

Different channel pillars 131A and 131B of the channel structure 131 may form different memory cell strings. According to an embodiment, the first channel pillar 131A may serve as a channel region which couples the plurality of memory cells of the first memory cell string CS1 in series with each other, and the second channel pillar 131B may serve as a channel region which couples the plurality of memory cells of the second memory cell string CS2 in series with each other.

Each of the memory layers 120A and 120B may include a blocking insulating layer 121 which extends along a sidewall of the hole 115, a data storage layer 123 which extends along an inner wall of the blocking insulating layer 121, and a tunnel insulating layer 125 which extends along an inner wall of the data storage layer 123. The blocking insulating layer 121 may include an insulating material which is capable of blocking charges. The tunnel insulating layer 125 may include an insulating material which enables charge tunneling. The blocking insulating layer 121 may include an insulating layer which has a dielectric constant greater than the dielectric constant of the tunnel insulating layer 125.

The data storage layer 123 may include a material capable of storing data being changed by using Fowler-Nordheim tunneling. According to an embodiment, the data storage layer 123 may include a charge trap insulating layer or an insulating layer which includes conductive nanodots. The charge trap insulating layer may include a silicon nitride layer. However, the invention is not limited thereto. The data storage layer 123 may include a material layer which is capable of storing information on the basis of another operating principle other than Fowler-Nordheim tunneling. According to an embodiment, the data storage layer 123 may include a phase-change material layer, a ferroelectric layer, or the like. In this embodiment, the channel structure 131 may be replaced with an electrode structure which includes pillar type electrodes which are separated from each other.

The blocking insulating layer 121, the data storage layer 123, and the tunnel insulating layer 125 of the memory layer 120 may form the first memory portion 120A between the first channel pillar 131A and the gate stack 110. The blocking insulating layer 121, the data storage layer 123, and the tunnel insulating layer 125 of the memory layer 120 may form the second memory portion 120B between the second channel pillar 131B and the gate stack 110. Referring now to FIGS. 4, 5A and 5B, each of the first to third conductive layers 113A to 113C may include a first area 113AR1 corresponding to a first side area AR1 of the gate stack 110, a second area 113AR2 corresponding to a second side area AR2 of the gate stack 110, and a third area 113AR3 corresponding to an intermediate area AR3 of the gate stack 110.

The first side area AR1 and the first area 113AR1 may be extends along an exterior surface of the first channel pillar 131A. The second side area AR2 and the second area 113AR2 may be extends along an exterior surface of the second channel pillar 131B. The intermediate area AR3 may be located between the first side area AR1 and the second side area AR2, and the third area 113AR3 may be located between the first area 113AR1 and the second area 113AR2.

The first area 113AR1 may contact the first memory portion 120A of the memory layer 120 and control operations of the first channel pillar 131A. The second area 113AR2 may contact the second memory portion 120B of the memory layer 120 and control operations of the second channel pillar 131B. The third area 113AR3 may couple the first area 113AR1 and the second area 113AR2 and extend along a portion of a sidewall of the hole 115 which is opened by the channel structure 131. The third area 113AR3 may surround the insulating pillar 135 without interposing the channel structure 131. At least one of the blocking insulating layer 121, the data storage layer 123, and the tunnel insulating layer 125 of the memory layer 120 may extend between the insulating pillar 135 and the third area 113AR3 of each of the first to third conductive layers 113A to 113C.

The first to third areas 113AR1 to 113AR3 of each of the first to third conductive layers 113A to 113C may extend around the hole 115. A first memory cell of the first memory cell string CS1 may be formed between the first channel pillar 131A and the first area 113AR1 of each of the first to third conductive layers 113A to 113C. A second memory cell of the second memory cell string CS2 may be formed between the second channel pillar 131B and the second area 113AR2 of each of the first to third conductive layers 113A to 113C.

A curved portion which defines an undercut region UC1 or UC2 may be formed on the sidewall of the hole 115. The undercut region UC1 or UC2 may include a first portion A11 or A21 in the second direction DR2 and a second portion A12 or A22 in the third direction DR3. The undercut region UC1 or UC2 may be located at a level where boundaries between the sub-stacks are located, or at a level where openings are coupled. According to an embodiment, the first undercut region UC1 may be located at a first level LV1 where the boundary between the first sub-stack 110A and the sub-stack 110B is located, and the second undercut region UC2 may be located at a second level LV2 where the boundary between the second sub-stack 110B and the third sub-stack 110C is located.

The channel structure 131 may extend in the first direction DR1 to cover the first portion A11 or A21 of the undercut region UC1 or UC2 so that the plurality of memory cells stacked in the first direction DR1 may be coupled in series with each other. In other words, each of the first channel pillar 131A and the second channel pillar 131B may extend from the first region P1 to the third region P3 of the cell plug CPL while covering the first portion A11 or A21 of the undercut region UC1 or UC2 so that the plurality of memory cells of the memory cell string CS1 or CS2 corresponding thereto may be coupled in series with each other.

The second portion A12 or A22 of the undercut region UC1 or UC2 may be opened by the channel structure 131. As a result, interference between memory cell strings which are individually controlled in the cell plug CPL may be reduced. According to an embodiment, the first channel pillar 131A and the second channel pillar 131B may open the second portion A12 or A22 of the undercut region UC1 or UC2 to reduce the interference between the first memory cell string CS1 and the second memory cell string CS2.

The second portion A12 or A22 of the undercut region UC1 or UC2 may have a width which is controlled to a range of 20 nm or less. Accordingly, a phenomenon in which the thickness of the channel layer formed on the sidewall of the hole 115 to form the channel structure 131 of the cell plug CPL is excessively increased locally in the undercut region UC1 or UC2 may be improved. Thus, the second portion A12 or A22 of the undercut region UC1 or UC2 may be opened without over-etching the channel layer when etching the channel layer to form the channel structure 131 of the cell plug CPL. As a result, loss in thickness of each of the first and second channel pillars 131A and 131B of the channel structure 131 in the second direction DR2 may be reduced.

The undercut region UC1 or UC2 may be defined by the difference in inner diameter between openings of the hole 115.

According to an embodiment, a top of the first opening 115A may be coupled to a bottom of the second opening 115B, and an inner diameter of the top of the first opening 115A may be greater than that of the bottom of the second opening 115B. Similarly, a top of the second opening 115B may be coupled to a bottom of the third opening 115C, and an inner diameter of the top of the second opening 115B may be greater than that of the bottom of the third opening 115C. The above-described difference in inner diameter between the first opening 115A and the second opening 115B may cause the second sub-stack 110B to protrude toward the center of the hole 115 to cover a portion of the first opening 115A. As a result, the first undercut region UC1 may be defined. Similarly, the above-described difference in inner diameter between the second opening 115B and the third opening 115C may cause the third sub-stack 110C to protrude toward the center of the hole 115 to cover a portion of the second opening 115B. As a result, the second undercut region UC2 may be defined.

The first to third regions P1 to P3 of the cell plug CPL may have the same structure as the first to third openings 115A to 115C of the hole 115.

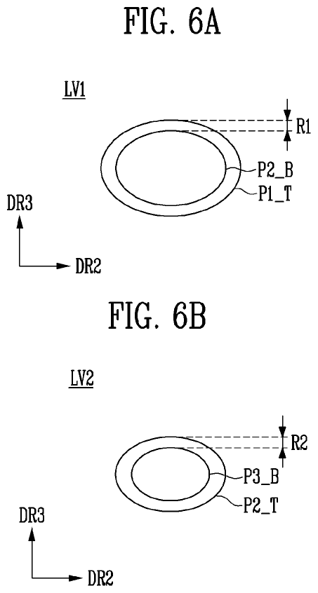

FIGS. 6A and 6B are diagrams illustrating a portion of a semiconductor memory device according to an embodiment of the present disclosure. FIGS. 6A and 6B are plan views illustrating the outline of the cell plug CPL as shown in FIGS. 5A and 5B. FIG. 6A is a plan view illustrating the first region P1 and the second region P2 of the cell plug CPL at the first level LV1 as shown in FIGS. 5A and 5B. FIG. 6B is a plan view illustrating the second region P2 and the third region P3 of the cell plug CPL at the second level LV2 as shown in FIGS. 5A and 5B.

Referring to FIGS. 5A and 5B and FIGS. 6A and 6B, an upper surface P1_T of the top end first region P1 of the cell plug CPL may be located at the first level LV1. Similarly, a lower surface P2_B of the bottom end of the second region P2 of the cell plug CPL may be located at the same first level LV1 and coupled to the upper surface P1_T of the top end of the first region P1. An upper surface P2_T of the top end of the second region P2 of the cell plug CPL may be located at the second level LV2. A lower surface P3_B of the bottom end of the third region P3 of the cell plug CPL may be located at the same second level LV2 and coupled to the upper surface P2_T of the top end of second region P2. Each of surfaces P1_T, P2_B, P2_T, and P3_B may have an elliptically-shaped horizontal cross section.

In the cell plug CPL, the area of the upper surface P1_T of the first region P1 may be greater than the area of the lower surface P2_B of the second region P2. The upper surface P1_T of the first region P1 may protrude in a range R1 of 20 nm or less, toward a side portion (e.g., DR2 and DR3) as compared to the lower surface P2_B of the second region P2.

In the cell plug CPL, the area of the upper surface P2_T of the second region P2 may be greater than the area of the lower surface P3_B of the third region P3. The upper surface P2_T of the second region P2 may protrude in a range R2 of 20 nm or less, toward a side portion (e.g., DR2 and DR3) more than the lower surface P3_B of the third region P3.

To control the range R1 or R2 in which the cell plug CPL protrudes to the side portion and the width of the undercut region (A11 or A21) to be 20 nm or less, a sidewall slope θ2 of the second region P2 of the cell plug CPL may be set closer to 90° than each of a sidewall slope θ1 of the first region P1 and a sidewall slope θ3 of the third region P3. In other words, the sidewall slope of the second region P2 may be steeper than the sidewall slope of each of the first and third regions P1 and P3. A length of the second region P2 of the cell plug CPL in the first direction DR1 may be less than that of each of the first region P1 and the third region P3 of the cell plug CPL in the first direction DR1.

The second sub-stack 110B which surrounds the shorter second region P2 may have a height in the first direction DR1 which is less than that of each of the first sub-stack 110A which surrounds the longer first region P1 and the third sub-stack 110C which surrounds the longer third region P3. According to an embodiment, the first sub-stack 110A may include the plurality of first interlayer insulating layers 111A and the plurality of first conductive layers 113A which are stacked alternately with each other in the first direction DR1. The second sub-stack 110B may include the second interlayer insulating layer 111B and the second conductive layer 113B which are stacked on top of each other. The second interlayer insulating layer 111B and the second conductive layer 113B may be fewer than the plurality of first interlayer insulating layers 111A and the plurality of conductive layers 113A. The third sub-stack 110C may include the plurality of third interlayer insulating layers 111C and the plurality of third conductive layers 113C which are stacked on top of each other. The third interlayer insulating layers 111C and the third conductive layers may be more than the second interlayer insulating layer 111B and the second conductive layer 113B.

As shown in FIGS. 5A and 5B, the second interlayer insulating layer 111B of the second sub-stack 110B may be adjacent to the uppermost first conductive layer, of the plurality of first conductive layers 113A, in the first direction DR1, and the second conductive layer 113B of the second sub-stack 110B may be adjacent to the lowermost third interlayer insulating layer, of the plurality of third interlayer insulating layers 111C, in the first direction DR1. However, the present disclosure is not limited thereto. The stacked layers of each of the first to third sub-stacks 110A to 110C may be designed in various ways.

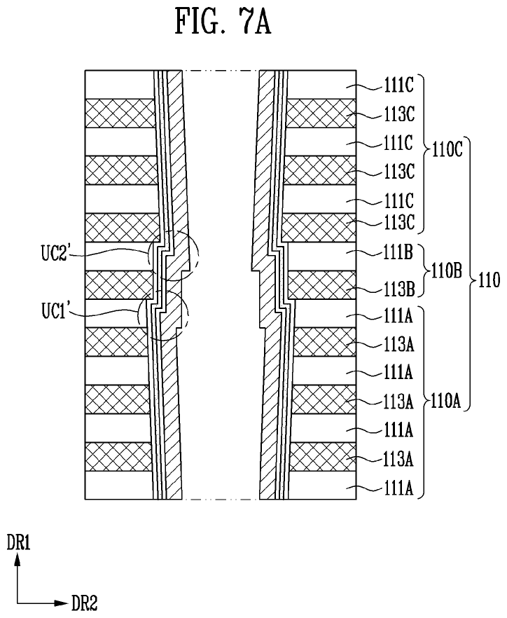

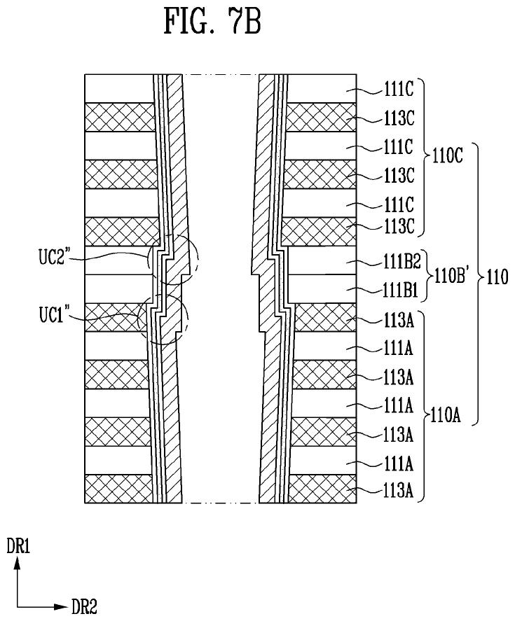

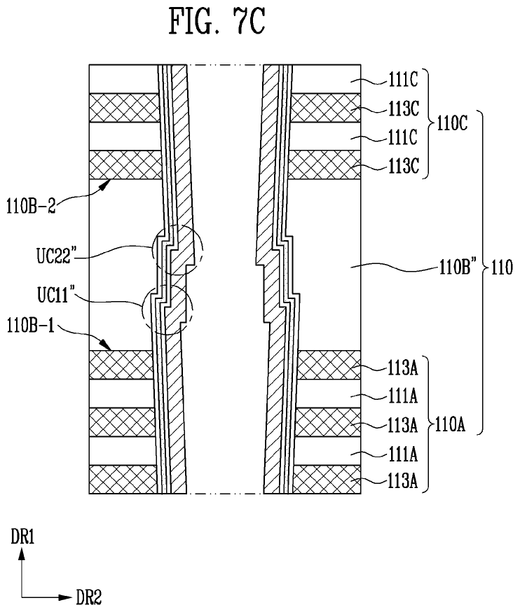

FIGS. 7A, 7B, and 7C are cross-sectional diagrams illustrating a semiconductor memory device according to embodiments of the present disclosure.

FIGS. 7A, 7B, and 7C are vertical cross-sectional diagrams illustrating portions of a semiconductor memory device according to embodiments of the present disclosure. FIGS. 7A to 7C are vertical cross-sectional diagrams of the semiconductor memory device taken along line I-I′ shown in FIG. 4. A description of some portions which are the same as those in the embodiments of FIGS. 5A and 5B will be omitted or simplified.

Referring to FIG. 7A, similarly to FIGS. 5A and 5B, the first sub-stack 110A may include the plurality of first interlayer insulating layers 111A and the plurality of first conductive layers 113A. The second sub-stack 110B may include the second interlayer insulating layer 111B and the second conductive layer 113B. The third sub-stack 110C may include the plurality of third interlayer insulating layers 111C and the plurality of third conductive layers 113C.

According to the embodiment shown in FIG. 7A, the second conductive layer 113B of the second sub-stack 110B may be vertically adjacent to but located above the uppermost interlayer insulating layer of the first interlayer insulating layers 111A, in the first direction DR1. The second interlayer insulating layer 111B of the second sub-stack 110B may be vertically adjacent to but located below the lowermost third conductive layer, of the plurality of third conductive layers 113C, in the first direction DR1.

A first undercut region UC1′ may be defined by the second conductive layer 113B which protrudes toward the side portion more than the uppermost first interlayer insulating layer. A second undercut region UC2′ may be defined by the lowermost third conductive layer which protrudes toward the side portion more than the second interlayer insulating layer 111B.

Referring to FIGS. 7B and 7C, similarly to FIGS. 5A and 5B, each of the first sub-stack 110 and the third sub-stack 110C may include the plurality of interlayer insulating layers 111A or 111C and the plurality of conductive layers 113A or 113C which are alternately stacked in the first direction DR1. A second sub-stack 110B′ or 110B″ may include at least one interlayer insulating layer.

Referring to FIG. 7B, the second sub-stack 110B′ may include a lower interlayer insulating layer 111B1 and an upper interlayer insulating layer 111B2 which are stacked on top of each other in the first direction DR1. The lower interlayer insulating layer 111B1 may be vertically adjacent to but located above the uppermost conductive layer of the conductive layers 113A of the first sub-stack 110A, in the first direction DR1. The upper interlayer insulating layer 111B2 may be adjacent to but located below the lowermost conductive layer of the conductive layers 113C of the third sub-stack 110C, in the first direction DR1.

A first undercut region UC1″ may be defined by the lower interlayer insulating layer 111B1 which protrudes toward the side portion more than the conductive layer 113A of the first sub-stack 110A. A second undercut region UC2″ may be defined by the conductive layer 113C of the third sub-stack 110C which protrudes towards the side portion more than the upper interlayer insulating layer 111B2.

Referring to FIG. 7C, the second sub-stack 110B″ may include a single insulating layer or at least two insulating layers. A bottom surface 110B-1 of the second sub-stack 110B″ may be vertically adjacent to but above the uppermost conductive layer of the conductive layers 113A of the first sub-stack 110A, in the first direction DR1. A top surface 110B-2 of the second sub-stack 110B″ may be vertically adjacent to but below the lowermost conductive layer of the conductive layers 113C of the third sub-stack 110C, in the first direction DR1. The first undercut region UC11″ and the second undercut region UC22″ may be located at different levels within the insulating layer of the second sub-stack 110B″.

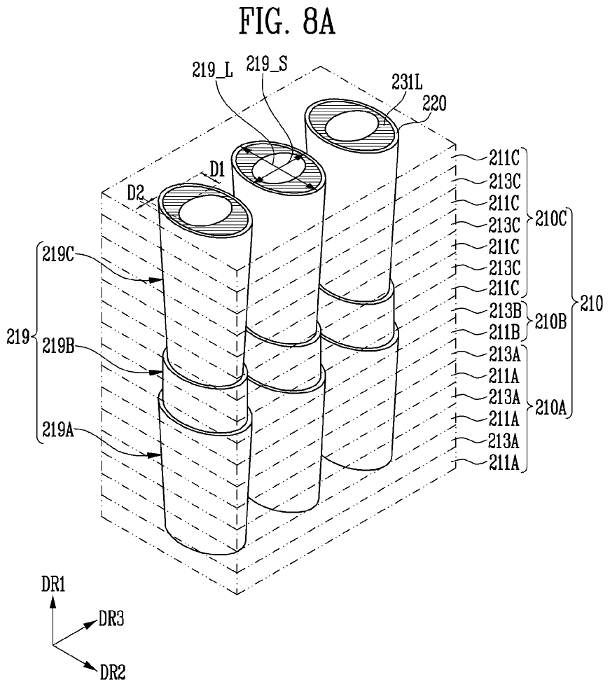

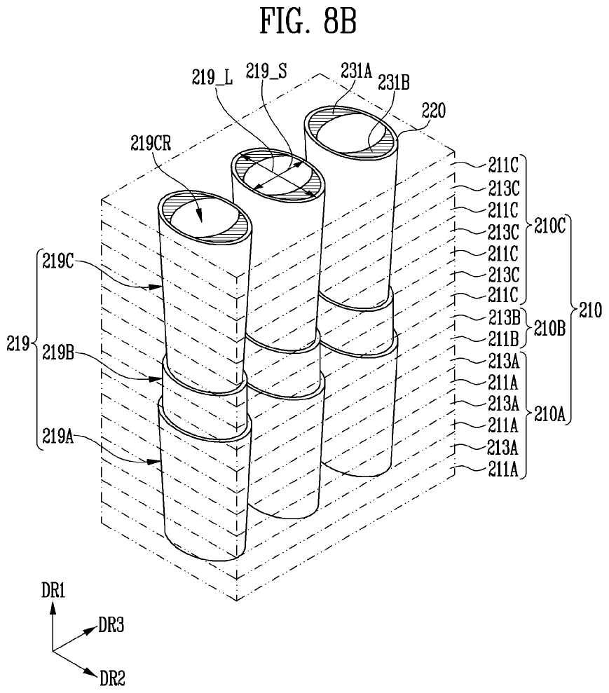

FIGS. 8A and 8B are perspective views diagrams illustrating steps of a method of manufacturing a semiconductor memory device according to embodiments of the present disclosure.

FIGS. 8A and 8B each illustrate a stack 210 which includes a hole 219. FIGS. 8A and 8B are perspective views illustrating the stack 210 for the convenience of recognition with respect to a structure located in the hole 219.

Referring to FIG. 8A, the stack 210 may be formed on a lower structure (not shown). According to an embodiment, the lower structure may include the second structure ST2 and the doped semiconductor structure DPS as described above with reference to FIG. 3A. According to another embodiment, the lower structure may include the second structure ST2, the first semiconductor layer L1, and a sacrificial layer between the first semiconductor layer L1 and the third semiconductor layer L3. The sacrificial layer may be replaced by the second semiconductor layer L2 as shown in FIG. 3B during a subsequent process. According to another embodiment, the lower structure may be a sacrificial substrate which includes a silicon wafer. The entirety or a portion of the sacrificial substrate may be replaced by the doped semiconductor structure DPS shown in FIG. 3C or 3D during a subsequent process. The remaining sacrificial substrate may correspond to the semiconductor layer 50 shown in FIG. 3D.

The stack 210 may be formed on the lower structure according to the above-described various embodiments. The stack 210 may include the plurality of first material layers 211A, 211B, and 211C and the plurality of second material layers 213A, 213B, and 213C which are alternately stacked on each other in the first direction DR1. Each of the plurality of first material layers 211A, 211B, and 211C and the plurality of second material layers 213A, 213B, and 213C may be in the form of a plate which extends in the second direction DR2 and the third direction DR3 crossing each other in a plane.

The plurality of second material layers 213A, 213B, and 213C may have a material having an etch selectivity with respect to the plurality of first material layers 211A, 211B, and 211C. According to an embodiment, the plurality of first material layers 211A, 211B, and 211C may include an insulating material such as a silicon oxide layer and a silicon oxynitride layer, and the plurality of second material layers 213A, 213B, and 213C may include a sacrificial insulating material such as a silicon nitride layer. The sacrificial insulating material may be replaced by a conductive material after a cell plug is formed. The conductive material may include at least one of a doped semiconductor layer and a metal layer. When the conductive material includes a metal layer, the conductive metal nitride layer may be formed as a metal barrier layer. According to another embodiment, the plurality of first material layers 211A, 211B, and 211C may include a sacrificial material such as an undoped silicon layer, and the plurality of second material layers 213A, 213B, and 213C may include a conductive material such as a doped silicon layer. The sacrificial material may be replaced by an insulating material such as a silicon oxide layer or a silicon oxynitride layer after the cell plug is formed.

Contrary to the above description, however, the plurality of first material layers 211A, 211B, and 211C may include an insulating material, and the plurality of second material layers 213A, 213B, and 213C may include a conductive material. According to an embodiment, the plurality of first material layers 211A, 211B, and 211C may include a silicon oxide layer, a silicon oxynitride layer, and the like, and the plurality of second material layers 213A, 213B, and 213C may include at least one of a doped semiconductor layer and a metal layer. The plurality of second material layers 213A, 213B, and 213C may further include a conductive metal nitride layer other than the metal layer.

The stack 210 may include the hole 219. The hole 219 may extend in the first direction DR1 so as to extend through the plurality of first material layers 211A, 211B, and 211C and the plurality of second material layers 213A, 213B, and 213C. The hole 219 may have an elliptical cross section. A major axis 219_L of the elliptical shape may be along the second direction DR2 and a minor axis 219_S of the elliptical shape may be along the third direction DR3.

Forming the stack 210 which includes the hole 219 may include forming a first sub-stack 210A which includes a first opening 219A, forming a second sub-stack 210B which includes a second opening 219B on the first sub-stack 210A, and forming a third sub-stack 210C which includes a third opening 219C on the second sub-stack 210B.

The first sub-stack 210A may include a first group of the first material layer 211A and a first group of the second material layer 213A which are stacked alternately in the first direction DR1 of the plurality of first material layers 211A, 211B, and 211C and the plurality of second material layers 213A, 213B, and 213C. The first opening 219A may have an elliptical cross section and extend in the first direction DR1 to extend through the first sub-stack 210A. The inside of the first opening 219A may be filled with a first gap-filling layer (not shown) before the second sub-stack 210B is formed.

The second sub-stack 210B may include a second group of the first material layer 211B and a first group of the second material layer 213B which are staked alternately in the first direction DR1 of the plurality of first material layers 211A, 211B, and 211C and the plurality of second material layers 213A, 213B, and 213C. The second opening 219B may have an elliptical cross section and extend in the first direction DR1 to penetrate the second sub-stack 210B. The inside of the second opening 219B may be filled with a second gap-filling layer (not shown) before the third sub-stack 210C is formed. The stacking number of the first material layer 211B in the second group and the second material layer 213B in the second group may be less than that of the first material layer 211A in the first group and the second material layer 213A in the first group. Therefore, when the second opening 219B is formed, a sidewall slope of the second opening 219B may be closer to 90° than that of the first opening 219A.

The third sub-stack 210C may include a third group of the first material layer 211C and a third group of the second material layer 213C which are stacked alternately in the first direction DR1 of the plurality of first material layers 211A, 211B, and 211C and the plurality of second material layers 213A, 213B, and 213C. The third opening 219C may have an elliptical cross section and extend in the first direction DR1 to penetrate the third sub-stack 210C. The stacking number of the first material layer 211C in the third group and the second material layer 213C in the third group may be greater than that of the first material layer 211B in the second group and the second material layer 213B in the second group. Therefore, the sidewall slope of the third opening 219C may be less close to 90° than the sidewall slope of the second opening 219B.

After the third opening 219C is formed, the first gap-filling layer and the second gap-filling layer may be removed through the third opening 219C to thereby expose the first opening 219A and the second opening 219B. The first to third openings 219A to 219C may be coupled to each other to form the hole 219.

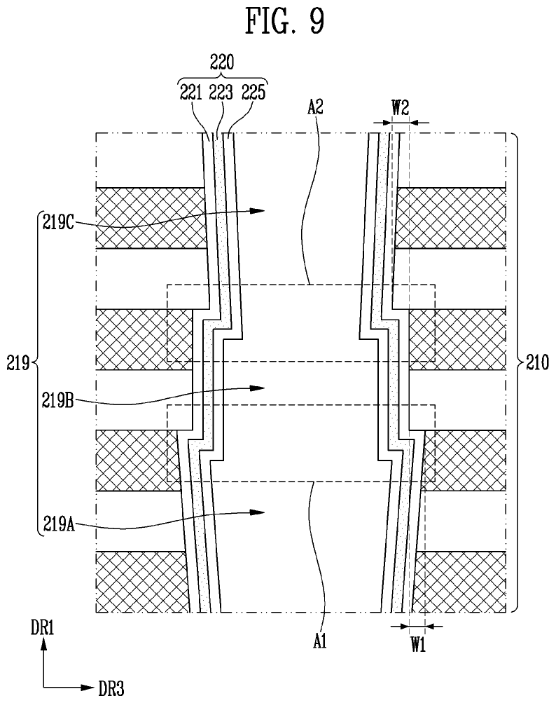

After the hole 219 is formed, a memory layer 220 may be formed along the sidewall of the hole 219. The memory layer 220 may include a blocking insulating layer 221, a data storage layer 223, and a tunnel insulating layer 225 as shown in FIG. 9. The blocking insulating layer 221, the data storage layer 223, and the tunnel insulating layer 225 may include various materials as exemplified in FIGS. 5A and 5B.

Referring to FIG. 8A, a channel layer 231L may be formed in the hole 219. The channel layer 231L may be formed along an inner wall of the memory layer 220. The channel layer 231L may include silicon (Si), germanium (Ge), or a mixture thereof.

Because the hole 219 has the elliptical shape, the deposition amount of the channel layer 231L may be controlled such that the channel layer 231L may be deposited at different thicknesses in directions along which the major axis 219_L and the minor axis 219_S defined by the hole 219 run. The channel layer 231L may have a first thickness D1 along the major axis 219_L of the hole 219 and a second thickness D2 along the minor axis 219_S of the hole 219. The deposition amount of the channel layer 231L may be controlled such that the first thickness D1 may be greater than the second thickness D2 (D1>D2).

Referring to FIG. 8B, by etching the channel layer 231L shown in FIG. 8A through an opened central region 219CR of the hole 219, the channel layer 231L may be separated into a first channel pillar 231A and a second channel pillar 231B. The first channel pillar 231A and the second channel pillar 231B may be separated from each other in the second direction DR2 along which the major axis 219_L of the hole 219 runs.

The channel layer 231L shown in FIG. 8A may be etched using a wet etch process. During the wet etch process, the channel layer 231L may be etched to a thickness which is less than the first thickness D1. And the channel layer 231L may be etched to a thickness equal to or greater than the second thickness D2 as described above with reference to FIG. 8A.

The channel layer may be etched to different amounts in the second direction DR2 corresponding to the major axis 219_L of the hole 219 and the third direction DR3 corresponding to the minor axis 219_S of the hole 219. Because different lateral areas of the channel layer may be exposed by an etchant for wet etching in the second direction DR2 and the third direction DR3. More specifically, during the wet etch process, a loss in thickness of the channel layer in the second direction DR2 may be less than that of the channel layer in the third direction DR3.

As described above with reference to FIG. 8A, because the first thickness D1 of the channel layer 231L is greater than the second thickness D2, even if the channel layer 231L is etched to the second thickness D2 during the etch process described with reference to FIG. 8B, a portion of the channel layer 231L which has the first thickness D1 may remain as the first channel pillar 231A and the second channel pillar 231B.

FIG. 9 is a vertical cross-sectional diagram illustrating a portion of the internal structure of the hole 219 taken along the minor axis 219_S of the hole 219 shown in FIG. 8B.

Referring to FIG. 9, the hole 219 which extends through the stack 210 may include the second opening 219B which couples the first opening 219A and the third opening 219C to each other. The second opening 219B may have a sidewall slope which is closer to 90° than that of each of the first opening 219A and the third opening 219C.

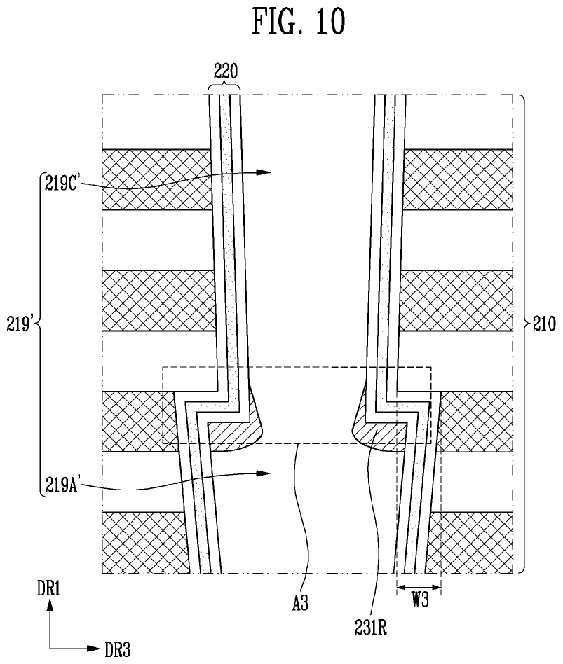

FIG. 10 is a vertical cross-sectional diagram illustrating a semiconductor memory device according to a comparative example.

A hole 219′ shown in FIG. 10 may have an elliptical cross section similar to that of the hole 219 described above with reference to FIGS. 8A and 8B. FIG. 10 is a cross-sectional diagram illustrating the internal structure of the hole 219′ taken along the minor axis of the hole 219′.

Referring to FIG. 10, the hole 219′ may include a lower opening 219A′ and an upper opening 219C′. The lower opening 219A′ and the upper opening 219C′ may be adjacent in the first direction DR1 and may be directly coupled to each other. The sidewall slope of each of the lower opening 219A′ and the upper opening 219C′ may be less close to 90° than the second opening 219B shown in FIG. 9. For example, the lower opening 219A′ may have the same sidewall slope as the first opening 219A shown in FIG. 9, and the upper opening 219C′ may have the same sidewall slope as the third opening 219C shown in FIG. 9.

Referring to FIGS. 9 and 10, when the first opening 219A and the third opening 219C are coupled to each other while interposing the second opening 219B whose sidewall slope is controlled to be relatively close to 90°, width differences at connection points between the openings may be reduced as compared to when the first opening 219A and the third opening 219C are directly coupled to each other without interposing the second opening 219B. More specifically, it would be easier to control a width W1 or W2 of an undercut region A1 or A2 at the connection points between the first to third openings 219A to 219C to be 20 nm or less than to control a width W3 of the undercut region A3 at the connection point between the lower opening 219A′ and the upper opening 219C′.

When the width W1 or W2 of the undercut region A1 or A2 is controlled to 20 nm or less, the thickness of the channel layer 231L may be prevented from being locally excessively increased in the undercut region A1 or A2 during the deposition of the channel layer 231L shown in FIG. 8A. In addition, as described above with reference to FIG. 8B, when the channel layer is etched, a portion of the channel layer which overlaps the minor axis 219_S of the hole 219 may be stably removed.

When the width W3 of the undercut region A3 is increased to a range exceeding 20 nm, even if a portion of the channel layer is etched to expose the memory layer 220, another portion of the channel layer may remain at an overlapping area with the minor axis of the hole 219′ in the undercut region A3. This may be defined as a remaining channel layer 231R. The remaining channel layer 231R may cause interference between the first channel pillar and the second channel pillar.

According to an embodiment of the present disclosure, it would be easier to control the width W1 or W2 of the undercut region A1 or A2 to be 20 nm or less. Therefore, as shown in FIG. 8B, the first channel pillar 231A and the second channel pillar 231B may be stably separated from each other in the hole 219, thereby reducing the generation of the remaining channel layer 231R.

After the first channel pillar 231A and the second channel pillar 231B shown in FIG. 8B are formed, a subsequent process of filling the central region 219CR of the hole 219 with an insulating pillar may be performed.

The first to third sub-stacks 210A to 210C or the stack 210 and the first to third openings 219A to 219C as shown in FIGS. 8A, 8B, and 9 are shown on the basis of the structure corresponding to the undercut regions UC1 and UC2 shown in FIGS. 5A and 5B. However, embodiments of the present disclosure are not limited thereto. According to another embodiment, the stacking numbers and kinds of material layers for providing the first to third sub-stacks 210A to 210C shown in FIGS. 8A and 8B may vary depending on the undercut regions UC1′ and UC2′ shown in FIG. 7A, the undercut regions UC1″ and UC2″ shown in FIG. 7B, or the undercut regions UC11″ and UC22″ shown in FIG. 7C.

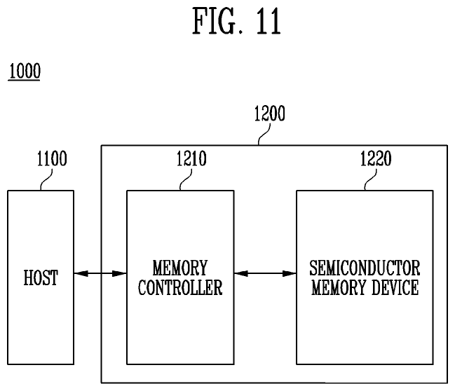

FIG. 11 is a block diagram illustrating an electronic system 1000 including a semiconductor memory device according to embodiments of the present disclosure.

Referring to FIG. 11, the electronic system 1000 may be a computing system, a medical device, a communication device, a wearable device, a memory system, or the like. The electronic system 1000 may include a host 1100 and a storage device 1200.

The host 1100 may store data in a storage device 1200, or may read the stored data from the storage device 1200 on the basis of an interface. The interface may include at least one of a Double Data Rate (DDR) interface, a Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics interface (IDE), a Firewire interface, a Universal Flash Storage (UFS) interface, and a Nonvolatile Memory express (NVMe) interface.

The storage device 1200 may include a memory controller 1210 and a semiconductor memory device 1220. According to an embodiment, the storage device 1200 may be a storage medium such as a solid state drive (SSD), a universal serial bus (USB) memory, or the like.

The memory controller 1210 may store data in the semiconductor memory device 1220, or may read data stored in the semiconductor memory device 1220 in response to control of the host 1100.

The semiconductor memory device 1220 may include a single memory chip or a plurality of memory chips. The semiconductor memory device 1220 may store data or output stored data in response to control of the memory controller 1210.

The semiconductor memory device 1220 may be a non-volatile memory device. The semiconductor memory device 1220 may include the gate stack and the cell plug as described above with reference to FIGS. 4, 5A, 5B, 6A, 6B, 7A, 7B, and 7C. According to an embodiment, the semiconductor memory device 1220 may include a channel structure which extends in a first direction along a hole penetrating the gate stack. The channel structure may include a first channel pillar and a second channel pillar which are spaced apart from each other in a second direction crossing a longitudinal direction of the hole. A portion of a sidewall of the hole at a position corresponding between the first and second channel pillars may be opened by the channel structure.

According to an embodiment of the present disclosure, defects occurring during a process of separating channel pillars from each other in a hole may be reduced to improve the operational reliability of a semiconductor memory device.

What is claimed is:

1. A semiconductor memory device, comprising:
a gate stack comprising a first sub-stack, a second sub-stack, and a third sub-stack, the first to third sub-stacks being stacked on top of each other in a first direction; and
a cell plug extending in the first direction penetrating the first sub-stack, the second sub-stack, and the third sub-stack,
wherein the cell plug comprises a first region penetrating the first sub-stack, a second region penetrating the second sub-stack, and a third region penetrating the third sub-stack, each of the first, second and third regions having top and bottom ends, each of the top and bottom ends having a corresponding area;
wherein the area of the top end of the first region of the cell plug is greater than the area of bottom end of the second region of the cell plug, and
wherein the upper end of the second region of the cell plug has an area greater than the area of the bottom end of the third region.

2. The semiconductor memory device of claim 1, wherein a length of the second region of the cell plug in the first direction is less than a length of each of the first and third regions of the cell plug in the first direction.

3. The semiconductor memory device of claim 1, wherein a sidewall slope of the second region of the cell plug is steeper than a sidewall slope of each of the first and third regions of the cell plug.

4. The semiconductor memory device of claim 1, wherein the first sub-stack comprises a plurality of first conductive layers and a plurality of first interlayer insulating layers stacked alternately with each other in the first direction,
wherein the second sub-stack comprises a second conductive layer and a second interlayer insulating layer, which are stacked in the first direction, and
wherein the third sub-stack comprises a plurality of third conductive layers and a plurality of third interlayer insulating layers, which are stacked alternately with each other in the first direction.

5. The semiconductor memory device of claim 4, wherein the second interlayer insulating layer of the second sub-stack and an uppermost first conductive layer of the plurality of first conductive layers, are adjacent to each other in the first direction, and
wherein the second conductive layer of the second sub-stack and a lowermost third interlayer insulating layer of the plurality of third interlayer insulating layers, are adjacent to each other in the first direction.

6. The semiconductor memory device of claim 4, wherein the second conductive layer of the second sub-stack and an uppermost first interlayer insulating layer of the plurality of first interlayer insulating layers, are adjacent to each other in the first direction, and
wherein the second interlayer insulating layer of the second sub-stack and a lowermost third conductive layer of the plurality of third conductive layers, are adjacent to each other in the first direction.

7. The semiconductor memory device of claim 1, wherein each of the first sub-stack and the third sub-stack comprises a plurality of conductive layers and a plurality of interlayer insulating layers stacked alternately with each other in the first direction, and
wherein the second sub-stack comprises an interlayer insulating layer adjacent to the conductive layers of each of the first sub-stack and the third sub-stack.

8. The semiconductor memory device of claim 1, wherein a height of the second sub-stack in the first direction is less than a height of each of the first and third sub-stacks in the first direction.

9. The semiconductor memory device of claim 1, wherein the first region of the cell plug protrudes toward a side portion 20 nm or less than the second region of the cell plug.

10. The semiconductor memory device of claim 1, wherein the second region of the cell plug protrudes toward a side portion 20 nm or less than the third region.

11. The semiconductor memory device of claim 1, wherein the cell plug has a first width in the second direction and a second width in a third direction, the second and third directions being orthogonal, and
wherein the first width is greater than the second width.

12. The semiconductor memory device of claim 1, wherein the cell plug comprises:
a channel structure including a first channel pillar and a second channel pillar extending from the first region to the third region; and
a memory layer located between the gate stack and each of the first channel pillar and the second channel pillar, and
wherein the first channel pillar and the second channel pillar are spaced apart from each other.

13. A semiconductor memory device, comprising:
a gate stack comprising a plurality of conductive layers spaced apart and stacked on each other in a first direction;
a hole extending in the first direction and penetrating the plurality of conductive layers;
a channel structure comprising a first channel pillar and a second channel pillar extending in the first direction, the channel structures being located in the hole and spaced apart from each other in a second direction, the second direction lying in a plane substantially parallel with the plurality of conductive layers; and
a memory layer located between the gate stack and each of the first channel pillar and the second channel pillar,
wherein a curved portion defining an undercut region is formed on a sidewall of the hole,
wherein the undercut region comprises a first portion in the second direction and a second portion in a third direction crossing the second direction in the plane, and
wherein the channel structure covers the first portion of the undercut region and opens the second portion of the undercut region.

14. The semiconductor memory device of claim 13, wherein the second portion of the undercut region has a width of 20 nm or less.

15. The semiconductor memory device of claim 13, wherein the hole extends to a first width in the second direction and a second width in the third direction, and
wherein the first width is greater than the second width.

16. The semiconductor memory device of claim 13, wherein in the plane, the hole has an elliptical horizontal cross section having a major axis aligned with the second direction.
